(19) United States
(12) Patent Application Publication
(10) Pub. No.: US 2025/0022679 A1
(43) Pub. Date: Jan. 16, 2025

(54) CHARGED PARTICLE BEAM MICROSCOPE IMAGE PROCESSING SYSTEM AND CONTROL METHOD THEREOF

(71) Applicant: HITACHI HIGH-TECH CORPORATION, Tokyo (JP)

(72) Inventor: Takashi AMANO, Tokyo (JP)

(73) Assignee: HITACHI HIGH-TECH CORPORATION, Tokyo (JP)

(21) Appl. No.: 18/688,490

(22) PCT Filed: Sep. 17, 2021
(86) PCT No.: PCT/JP2021/034419

§ 371 Date: Sep. 18, 2024

(51) Int. Cl. H01J 37/22; G06T 3/4038; H01J 37/28

(52) U.S. Cl. CPC H01J 37/222; G06T 3/4038; H01J 37/28; H01J 2237/221

(57) ABSTRACT

A charged particle beam microscope image processing system includes: a charged particle beam optical system configured to irradiate a sample with a charged particle beam, and output a detection signal of charged particles from the sample; and a control and image processing system configured to control the charged particle beam optical system, generate an image of the sample from the detection signal, store the generated image in a storage, and perform analysis processing on the image. The control and image processing system determines a performance of processing the image on the basis of an operation state of the control and image processing system, on the basis of the processing performance, determines a processing performance corresponding to a speed of storing the image into the storage, and generates the image and stores the image into the storage according to the determined processing performance.

### TECHNICAL FIELD

The present disclosure relates to a charged particle beam microscope image processing system and a control method thereof.

### BACKGROUND ART

A charged particle beam apparatus is used to observe a minute structure. For example, a semiconductor manufacturing process uses a charged particle beam apparatus that utilizes a charged particle beam such as an electron beam for the measurement or inspection of the dimensions and shape of semiconductor devices. An example thereof is a scanning electron microscope (SEM). The SEM generates an image by irradiating a sample desired to be observed with an electron beam (hereinafter a primary beam) generated from an electron source, detecting signal electrons generated by the irradiation by a detector, and converting the signal electrons into an electric signal.

The SEM used for such a purpose as length measurement or inspection is desired to provide a high throughput. Therefore, a multi-beam SEM has been proposed which irradiates the sample with a plurality of primary beams, and simultaneously detects a plurality of signal electron beams by a divided detector including a plurality of detectors.

The image obtained by the SEM is transferred to an image analyzing server that performs image processing for the measurement or defect detection of a target object. A configuration of the SEM and a server system is designed according to a processing performance set as a target, for example, a target scanning image transfer speed.

Scanned images are temporarily stored in a storage of the image analyzing server. Images in which measurement has already been performed or images from which no defect is detected, for example, are deleted from the storage. When a fault occurs in the image analyzing server, and consequently the performance of the image analyzing server is decreased, the storage becomes devoid of free space due to images that have not been subjected to the image processing for the measurement or the defect detection. Scanned images become unable to be stored in the storage, and therefore the scanning of the SEM is stopped.

### PRIOR ART DOCUMENT

### Patent Document

Patent Document 1: JP-2015-008059-A

### SUMMARY OF THE INVENTION

### Problem to be Solved by the Invention

In the conventional system, when the performance of the image analyzing server is decreased due to a fault or the like in the image analyzing server, the image processing does not catch up with image data being transferred, and the free space for storing images becomes less than a predetermined threshold value and thus becomes insufficient. When the free space becomes insufficient, scanning in the SEM is stopped, and consequently an overall measurement time or defect detection time of the target object can be greatly lengthened.

Hence, a technology is desired which can suppress the lengthening of an overall image processing time of the target object due to a decrease in the performance of the image analyzing server.

### Means for Solving the Problem

One aspect of the present disclosure is a charged particle beam microscope image processing system including: a charged particle beam optical system configured to irradiate a sample with a charged particle beam, and output a detection signal of charged particles from the sample; and a control and image processing system configured to control the charged particle beam optical system, generate an image of the sample from the detection signal, store the generated image in a storage, and perform analysis processing on the image. The control and image processing system determines a performance of processing the image on the basis of an operation state of the control and image processing system, on the basis of the processing performance, determines a processing performance corresponding to a speed of storing the image into the storage, and generates the image and stores the image into the storage according to the determined processing performance.

### Advantage of the Invention

According to one aspect of the present disclosure, it is possible to suppress the lengthening of an image processing time of a target object in the charged particle beam microscope image processing system.

### BRIEF DESCRIPTION OF THE DRAWINGS

FIG. 1 illustrates an example of a general configuration of a charged particle beam microscope image processing system.

FIG. 2 illustrates an example of a system configuration of an image processing system.

FIG. 3 illustrates an example of a hardware configuration of a control terminal.

FIG. 4 schematically illustrates an example of a software configuration of the control terminal.

FIG. 5 schematically illustrates an example of a software configuration of a storage control server.

FIG. 6 schematically illustrates an example of a software configuration of a user terminal.

FIG. 7 schematically illustrates an example of a software configuration of a job server.

FIG. 8 schematically illustrates an example of a software configuration of an image analyzing server.

FIG. 9A is a schematic diagram of assistance in explaining scanning intervals.

FIG. 9B illustrates a plurality of consecutive scanning lines.

FIG. 10 illustrates an example of a configuration of a processing performance table.

FIG. 11 illustrates an example of a configuration of a scanning performance table.

FIG. 12 illustrates an example of a configuration of the processing performance table.

FIG. 13 illustrates an example of a configuration of the scanning performance table.

FIG. 14 illustrates an example of a configuration of the processing performance table.

FIG. 15 illustrates an example of a configuration of the scanning performance table.

FIG. 16 illustrates an example of a configuration of the scanning performance table.

FIG. 17 illustrates an example of a configuration of the scanning performance table.

FIG. 18 illustrates a flowchart of an example of control processing on an SEM electron optical system by the control terminal.

FIG. 19 illustrates an example of a software configuration of the control terminal according to one embodiment of the present specification.

FIG. 20 illustrates an example of a GUI image for setting the processing performance table.

FIG. 21 illustrates an example of a GUI image for setting the scanning performance table.

### MODE FOR CARRYING OUT THE INVENTION

An embodiment will hereinafter be described with reference to the drawings. Incidentally, in all of the figures for describing the embodiment, identical elements are identified by the same reference numerals, and repeated description thereof will be omitted. An example of a charged particle beam apparatus to be described concretely in the following is an apparatus (electron microscope) for observing a sample by using an electron beam as a primary charged particle beam, and detecting a signal electron beam as a signal charged particle beam. Features of the present disclosure can be applied to another charged particle beam apparatus, for example, an apparatus that uses an ion beam as the primary charged particle beam and/or detects an ion beam as the signal charged particle beam.

In the following, description will be made of an example of a system that analyzes an image of a target object obtained by the charged particle beam microscope, and thereby detects a defect in the target object. The target object is, for example, a semiconductor wafer provided with a pattern. Features of the present disclosure can be applied to charged particle beam microscope image processing systems that perform other kinds of image analysis.

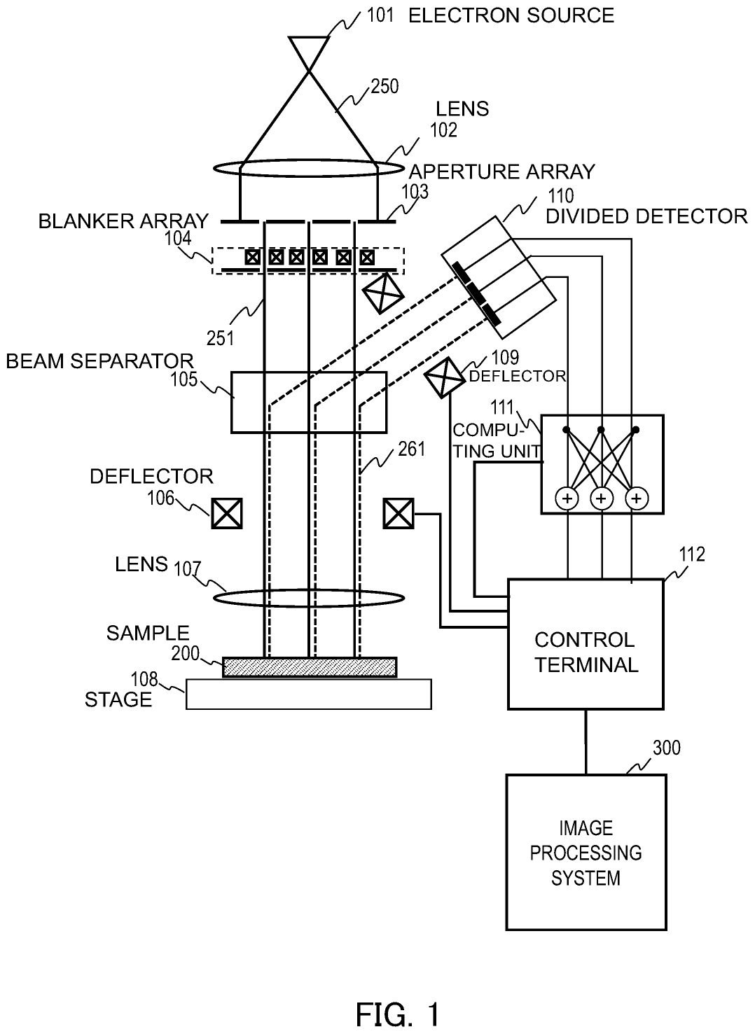

FIG. 1 illustrates an example of a general configuration of a charged particle beam microscope image processing system. FIG. 1 illustrates a scanning electron microscope (SEM) as an example of the charged particle beam microscope. The SEM is a sample (target object) observing apparatus using an electron beam. A configuration of the apparatus will first be described. FIG. 1 illustrates a multi-beam SEM that irradiates a sample with a plurality of primary beams (electron beams). The multi-beam SEM can shorten an observation time by simultaneously observing a wide field of view by the plurality of primary beams, and consequently improve throughput. The multi-beam SEM may have a configuration different from the configuration example illustrated in FIG. 1. In addition, a single beam SEM may be used.

The charged particle beam microscope image processing system illustrated in FIG. 1 includes a multi-beam SEM apparatus (hereinafter also referred to simply as a SEM apparatus) and an image processing system 300 that analyzes an image generated by the SEM apparatus. The SEM apparatus includes an electron optical system (lens barrel) and a SEM control device that controls the electron optical system and further generates an image from a detected signal. In the configuration example of FIG. 1, the SEM control device includes a computing unit 111 and a control terminal 112. The control terminal 112 controls constituent elements (electron optical elements) of the electron optical system.

The SEM electron optical system has a lens 102, an aperture array 103, a blanker array 104, a beam separator 105, a scanning deflector 106, and an objective lens 107 arranged in this order on the trajectory of a primary beam extracted from an electron source 101 (charged particle source) toward the sample 200. The lens 102 substantially collimates the primary beam from the electron source 101. The aperture array 103 is a plate having a plurality of apertures arranged one-dimensionally or two-dimensionally. The aperture array 103 divides the primary beam 250 from the lens 102 into a plurality of primary beams 251.

The blanker array 104 selectively passes the plurality of divided primary beams 251. The blanker array 104 includes deflectors corresponding to the plurality of divided primary beams 251, respectively, and an aperture array that has apertures corresponding to the plurality of divided primary beams 251, respectively. The control terminal 112 can select one or a plurality of primary beams 251 passing through the blanker array 104 by controlling the deflectors corresponding to the respective primary beams 251.

For the imaging of the sample 200, all of the primary beams 251 pass through the blanker array 104. The primary beams 251 passed through the blanker array 104 pass through the inside of the beam separator 105. The primary beams 251 are emitted from the beam separator 105, then pass through the scanning deflector 106 and the objective lens 107, and are thereafter converged on the sample 200. An exciting current of the scanning deflector 106 is controlled by the control terminal 112 such that the primary beams 251 respectively scan different regions on the sample 200.

A negative voltage, for example, is applied to the sample 200. The primary beams 251 are applied to the sample 200 after being decelerated. The primary beams 251 applied to the sample 200 interact with substances at or in the vicinity of the surface of the sample 200, and reflected electrons and other signal electrons occur according to the shape and materials of the sample. The signal electrons generated from the irradiation positions of the respective primary beams 251 on the sample 200 form signal electron beams 261.

The sample 200 is disposed on a stage 108. The primary beams 251 applied to the sample 200 respectively interact with the substances at or in the vicinity of the surface of the sample 200, and form the signal electron beams 261. The signal electron beams 261 pass through the objective lens 107 and the scanning deflector 106, and thereafter enter the beam separator 105. The beam separator 105 and a deflector 109 are arranged as optical elements that act on the signal electron beams 261.

The beam separator 105 deflects the signal electron beams 261, and thereby separates the trajectory of these signal electron beams from the trajectory of the primary beams 251. The signal electron beams 261 pass through the deflector 109, and reach a divided detector 110. The divided detector 110 includes a plurality of detectors. The number of the detectors is equal to or more than the number of the signal electron beams. The signal electron beams 261 reach the divided detector 110, and are detected by the respective corresponding detectors independently of each other.

The deflector 109 deflects the signal electron beams 261 from the beam separator 105. The control terminal 112 controls the deflector 109 in synchronism with the scanning deflector 106 such that the signal electron beams 261 generated on the basis of the respective primary beams 251 reach certain positions of the divided detector 110 irrespective of the scanning of the primary beams 251.

The divided detector 110 detects an intensity distribution of the plurality of signal electron beams 261, and converts the intensity distribution into a detection signal. The detection signal indicates detection intensities obtained by the plurality of respective detectors of the divided detector 110. The intensity distribution changes according to the shape and materials of the sample 200 at positions irradiated with the primary beams 251.

The computing unit 111 performs predetermined computation on the detection signal indicating the signal intensity distribution from the divided detector 110. The control terminal 112 generates a SEM image from a computation result of the computing unit 111, and displays the SEM image.

The multi-beam SEM can include other optical elements not illustrated. All of the optical elements are controlled by the control terminal 112. For example, the control terminal 112 controls an amount of current or voltage provided to each of the optical elements. By using the control terminal 112, a user can confirm and change settings of each of the optical elements. The control terminal 112 is, for example, a computer with an input-output device. Incidentally, the control terminal 112 may include the functions of the computing unit 111.

The image processing system 300 analyzes the image generated by the control terminal 112. In an example to be described in the following, the image processing system 300 detects a defect in the sample. For example, the control terminal 112 generates an image of a wafer provided with a pattern in which a plurality of dice are formed. The image processing system 300 compares an image of a die to be inspected with an image of an adjacent die. When the images of the two dice are identical to each other, it is determined that there is no defect in the dice. When there is a difference between the images of the two dice, the difference image indicates a defect. The image processing system 300 registers the image of the defect together with the position coordinates of the detected defect. Details of the processing of the image processing system 300 will be described later.

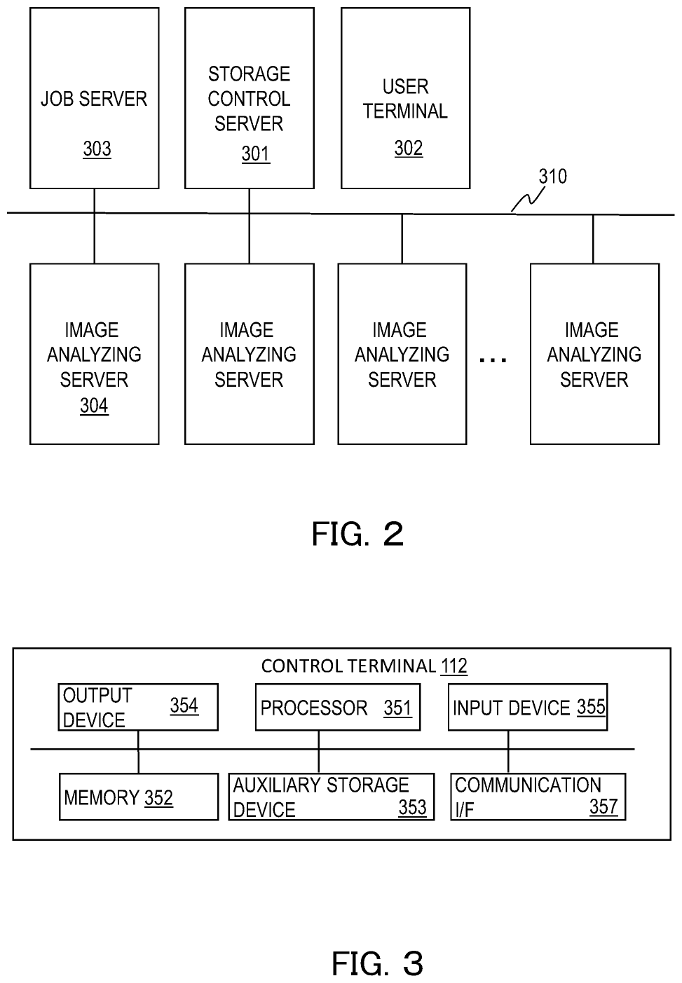

FIG. 2 illustrates an example of a system configuration of the image processing system 300. The image processing system 300 can include a plurality of computers connected via a network 310. In the configuration example of FIG. 2, the image processing system 300 includes a storage control server 301, a user terminal 302, a job server 303, and a plurality of image analyzing servers 304. In FIG. 2, four image analyzing servers are illustrated, and one image analyzing server is indicated by reference numeral 304 as an example. Incidentally, the various kinds of servers or the number of terminals in the image processing system 300 are not particularly limited. For example, a plurality of job servers 303 may be implemented, and the number of image analyzing servers may be one.

The image analyzing servers 304 each analyze an image imaged by the multi-beam SEM, and detect a defect in the image. The image analyzing servers 304 store an image analysis result (defect inspection result) in a storage within the image processing system 300. The plurality of image analyzing servers 304 can perform analysis processing on images different from each other in parallel. Because of the presence of the plurality of image analyzing servers 304, it is possible to improve the processing power of the image analysis, and continue defect detection processing even in a case where a fault has occurred in an image analyzing server.

The job server 303 generates jobs for the respective image analyzing servers 304, and allocates the jobs. The image analyzing servers 304 respectively execute the allocated jobs. The jobs are the image analysis and defect detection of the sample 200 as an inspection target object. The allocation of the jobs by the job server 303 enables efficient processing by the plurality of image analyzing servers 304 as a whole.

The storage control server 301 controls and manages the storage of the image processing system 300. The storage control server 301 constructs a logical storage by integrating storage areas provided by auxiliary storage devices within the image processing system 300. Images transferred from the control terminal 112 and results of the image analysis by the image analyzing servers 304 are stored in the storage. By deleting images in which no defect is detected by the analysis, it is possible to avoid a shortage of free space in the storage.

The user terminal 302 is a computer for the user to access the image processing system 300. The user can operate the image processing system 300 on the user terminal 302. According to user operation, the user terminal 302 receives a result of the defect detection from the image processing system 300, and presents the result to the user.

FIG. 3 illustrates an example of a hardware configuration of the control terminal 112. A similar configuration can be applied to the storage control server 301, the user terminal 302, the job server 303, and the image analyzing servers 304. In the present system, a part of the constituent elements illustrated in FIG. 2 may be omitted, and constituent elements not illustrated in FIG. 2 may be added.

The control terminal 112 includes a processor 351 as a computing unit, a memory (main storage device) 352, an auxiliary storage device 353, an output device 354, an input device 355, and a communication interface (I/F) 357. The above constituent elements are connected to each other by a bus. The memory 352, the auxiliary storage device 353, or a combination thereof is a storage device, and stores a program and data used by the processor 351.

The memory 352 is constituted by a semiconductor memory, for example. The memory 352 is used mainly to retain the program being executed and the data. The processor 351 performs various processing in accordance with the program stored in the memory 352. The processor 351 implements various functional sections by operating in accordance with the program. The auxiliary storage device 353 is constituted by a high-capacity storage device such as a hard disk drive or a solid state drive. The auxiliary storage device 353 is used to retain the program and the data for a long period of time.

The processor 351 can be constituted by a single processing unit or a plurality of processing units, and can include a single or a plurality of computing units or a plurality of processing cores. The processor 351 can be implemented as one or a plurality of central processing units, a microprocessor, a microcomputer, a microcontroller, a digital signal processor, a state machine, a logic circuit, a graphics processing device, a system on a chip, and/or an optional device that operates a signal on the basis of a control instruction.

The program and the data stored in the auxiliary storage device 353 are loaded into the memory 352 at a start time or at a necessary time, and the processor 351 executes the program. The various kinds of processing of the control terminal 112 are thereby performed.

The input device 355 is a hardware device for inputting an instruction, information, and the like to the control terminal 112. The output device 354 is a hardware device that presents various kinds of images for input and output. The output device 354 is, for example, a display device or a printing device. The communication I/F 357 is an interface for connection to the network.

The functions of the control terminal 112 can be implemented in a computer system constituted by one or more computers including one or more processors and one or more storage devices including a non-transitory storage medium. The plurality of computers communicate with each other via a network. For example, a part of a plurality of functions of the control terminal 112 may be implemented in one computer, and another part of the plurality of functions may be implemented in another computer.

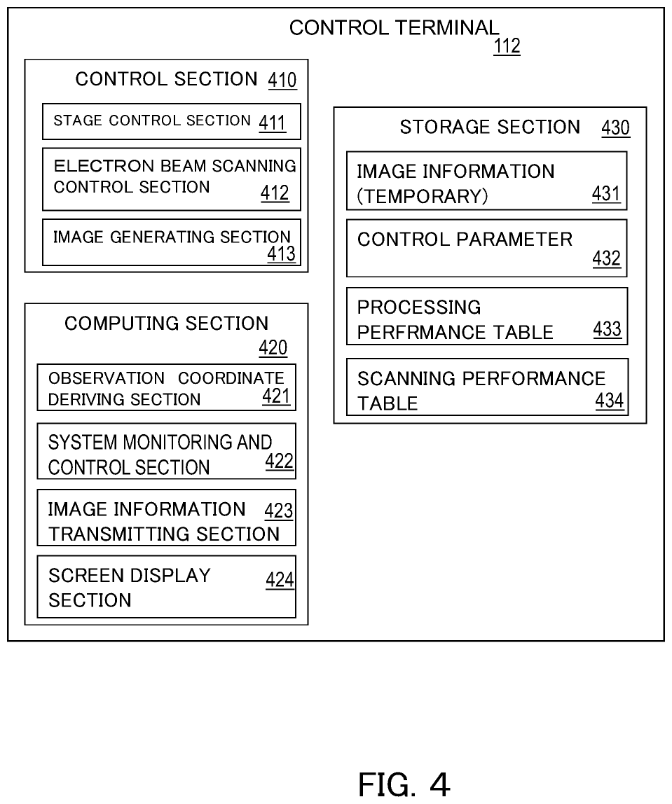

FIG. 4 schematically illustrates an example of a software configuration of the control terminal 112. The control terminal 112 generates an image of the sample 200 according to a signal from the SEM electron optical system while controlling the SEM electron optical system.

As will be described later, the control terminal 112 controls the scanning performance of the SEM or the performance of transferring image data to the image processing system 300 according to an operation state of the image processing system 300. It is thereby possible to control processing performance corresponding to a speed of storing image information into the storage of the image processing system 300. In the present specification, this processing performance will be referred to as image information transmission performance. The image information transmission performance can be expressed by a speed of information transmission in an image unit, that is, a time necessary to store one SEM image in the common storage of the image processing system 300.

Thus, even when the performance of the image processing system 300 is decreased, it is possible to continue image processing, and reduce a delay in the defect inspection time of the sample 200. Incidentally, as will be described later, the image processing may be stopped when the performance of the image processing system 300 is decreased significantly. The frequency or possibility of a stop of the image processing due to a decrease in the performance is reduced, and the delay in the defect inspection time can be reduced.

Each logical configuration of the control terminal 112 can be implemented by the processor that operates in accordance with an instruction code of the program or by a storage area of the storage device. In the configuration example illustrated in FIG. 4, the control terminal 112 includes a control section 410, a computing section 420, and a storage section 430.

A stage control section 411 included in the control section 410 controls movement and a stop of the stage 108. An electron beam scanning control section 412 controls the deflector 106 such that the electron beams are applied within a predetermined field of view. The control section 410 also controls constituent elements other than the above constituent elements. An image generating section 413 generates a digital image from a signal from the computing unit 111.

The storage section 430 temporarily stores image information 431. The image information 431 includes the generated digital image and supplementary information such as observation coordinates. The image information 431 (the digital image and the supplementary information) transferred to the image processing system 300 is deleted. The storage section 430 further stores a control parameter 432 of the SEM electron optical system, a processing performance table 433, and a scanning performance table 434. The control section 410 controls the SEM electron optical system in accordance with a parameter value represented by the control parameter 432.

The processing performance table 433 associates a specific operation state of the image processing system 300 with image processing performance. The scanning performance table 434 associates the processing performance of the image processing system 300 with the scanning performance of the SEM. The control terminal 112 refers to the processing performance table 433 and the scanning performance table 434 on the basis of the operation state of the image processing system 300, and controls the scanning performance of the SEM. Details of the processing performance table 433 and the scanning performance table 434 will be described later.

The computing section 420 includes an observation coordinate azimuth angle deriving section 421, a system monitoring and control section 422, an image information transmitting section 423, and a screen display section 424. The observation coordinate deriving section 421 derives observation coordinates as viewed from a wafer center in the image. The system monitoring and control section 422 monitors the image processing system 300, and instructs the control section 410 about a control method for the SEM electron optical system according to information about the operation state which information is obtained from the image processing system 300. For example, the system monitoring and control section 422 can instruct the control section 410 to change the control method by updating the control parameter 432.

The image information transmitting section 423 transfers, to the image processing system 300, the image information 431 stored in the storage section 430, that is, image data together with the supplementary information including the observation coordinates. Specifically, the image information transmitting section 423 specifies a storage position within the storage of the image processing system 300 and transmits the image information to the storage control server 301, and notifies the job server 303 of the transmission.

The screen display section 424 displays a control screen for the user to control the SEM as well as an observation image on an output device of the control terminal 112. The screen display section 424 performs image preprocessing such as smoothing and contrast adjustment and transformation such as the movement and rotation of the image. The screen display section 424 receives a user input on the control screen.

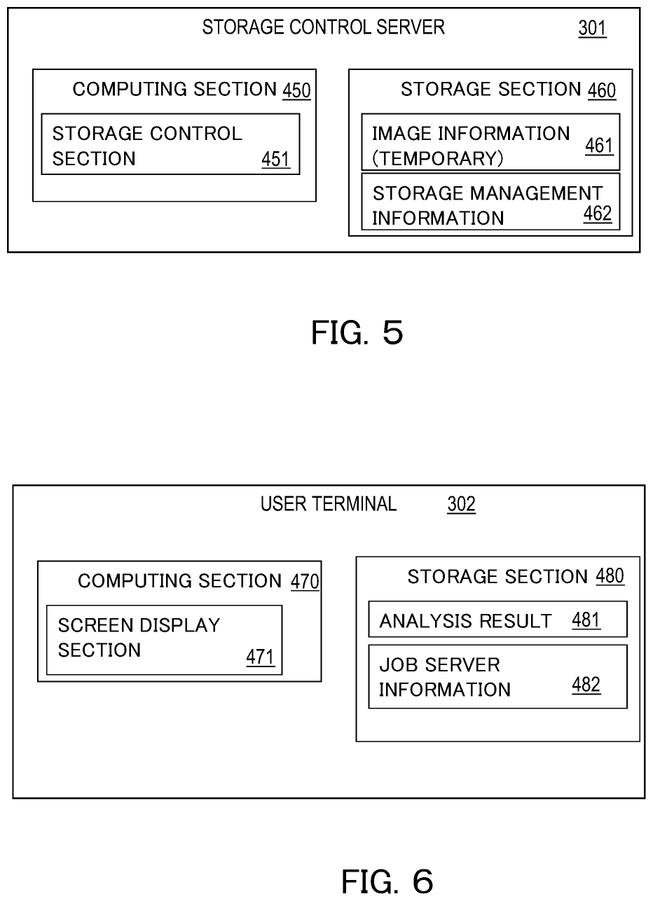

FIG. 5 schematically illustrates an example of a software configuration of the storage control server 301. The storage control server 301 controls and manages the common storage within the image processing system 300. Each logical configuration of the storage control server 301 can be implemented by a processor that operates according to an instruction code of a program or a storage area of a storage device.

The storage control server 301 includes a computing section 450 and a storage section 460. The computing section 450 includes a storage control section 451. The storage section 460 stores storage management information 462, and further temporarily stores image information 461 transferred from the control terminal 112. The storage control section 451 stores the image information 461 at an address of the common storage specified from the control terminal 112. A physical storage area of the common storage is provided by the auxiliary storage devices of the image analyzing servers 304 in the present example.

The storage control section 451 constructs a logical common storage within the image processing system 300 from physical storage areas of the plurality of image analyzing servers 304. The control terminal 112, the storage control server 301, the job server 303, and the image analyzing servers 304 can access the common storage via the storage control section 451, and store and read information in and from the common storage.

In addition, the control terminal 112, the storage control server 301, the job server 303, and the image analyzing servers 304 may transmit information necessary to refer to or update the storage management information 462 to the storage control section 451, obtain the storage management information 462 from the storage control section 451, directly communicate with a storage processing section 534 of a pertinent image analyzing server 304, and directly perform the storing and reading of the information.

The storage management information 462 manages information about the shared storage. The storage management information 462 is managed by the storage control section 451. The storage control section 451 refers to the storage management information 462, and updates the storage management information 462. The storage management information 462 includes information about the common storage such as the capacity of the common storage, address information of files stored therein, and the free space of the common storage. The storage management information 462 includes information that associates addresses of the common storage with the image analyzing servers 304.

FIG. 6 schematically illustrates an example of a software configuration of the user terminal 302. The user terminal 302 is an interface terminal for the user to access information within the image processing system 300. The user terminal 302 provides a GUI (Graphical User Interface) for the user to be able to check an inspection result of the sample 200 and set control parameters of the charged particle beam microscope image processing system. Each logical configuration of the user terminal 302 can be implemented by a processor that operates according to an instruction code of a program or a storage area of a storage device.

The user terminal 302 includes a computing section 470 and a storage section 480. The computing section 470 includes a screen display section 471. The storage section 480 stores an analysis result 481 and job server information 482. The analysis result 481 is an analysis result of an image of the sample 200 and a defect inspection result thereof. The job server information 482 includes information for the screen display section 471 to communicate with the job server 303.

The screen display section 471 provides a GUI for the user to access the charged particle beam microscope image processing system. The screen display section 471 refers to the job server information 482 and communicates with the job server 303, and sets control information of the charged particle beam microscope image processing system input by the user. In addition, the screen display section 471 requests an image analysis result (inspection result) of the sample 200 specified by the user from the job server 303, and receives the image analysis result. The received analysis result 481 (defect inspection result) is stored in the storage section 480. The analysis result 481 indicates, for example, a kind of a defect detected on the wafer and the position of the defect on the wafer.

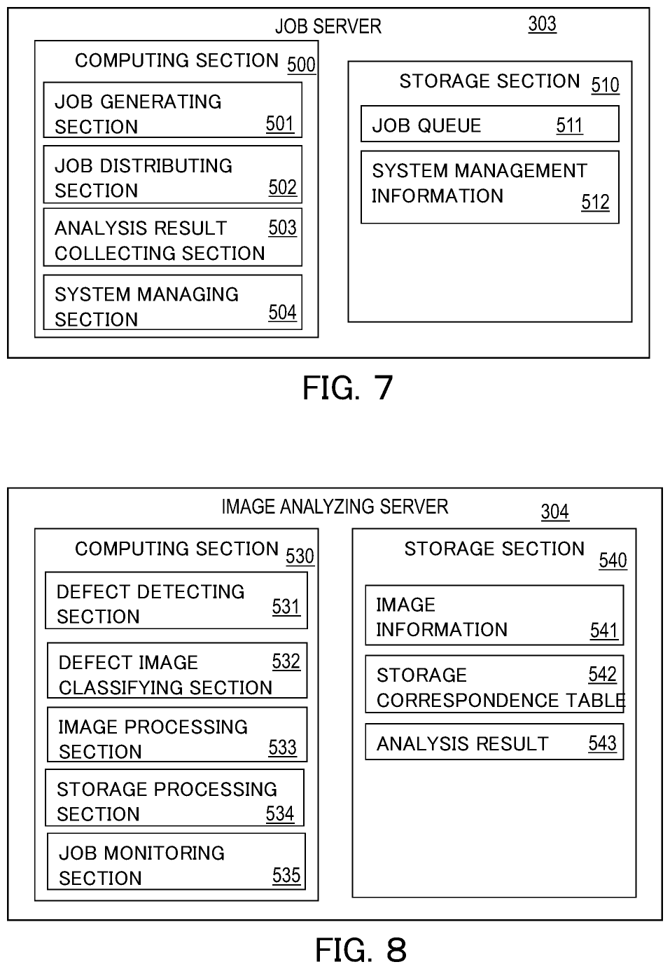

FIG. 7 schematically illustrates an example of a software configuration of the job server 303. The job server 303 allocates jobs of image analysis and defect detection to the plurality of image analyzing servers 304. Each logical configuration of the job server 303 can be implemented by a processor that operates according to an instruction code of a program or a storage area of a storage device.

The job server 303 includes a computing section 500 and a storage section 510. The computing section 500 includes a job generating section 501, a job distributing section 502, an analysis result collecting section 503, and a system managing section 504. The storage section 510 stores a job queue 511 and system management information 512.

The job generating section 501 generates jobs to be allocated to each of the image analyzing servers 304. When the image processing system 300 receives an image of the sample 200 and supplementary information from the control terminal 112, the job generating section 501 generates jobs for giving an instruction to analyze the received image. The transmission or reception of the image information may be notified from the control terminal 112 or the storage control server 301.

A job specifies the storage position of an analysis target image in the image processing system 300, the observation coordinates on the wafer of the image, and an analysis processing method, and gives an instruction for image analysis and defect detection. The job distributing section 502 transmits the job generated by the job generating section 501 to a selected image analyzing server 304.

The job distributing section 502 further updates the job queue 511 by adding information about the job assigned to the image analyzing server 304. The job queue 511 manages a job currently being executed and an image analyzing server 304 that is executing the job. When the job distributing section 502 receives a notification of an end of the analysis processing of the image from the image analyzing server 304, the job distributing section 502 deletes the information about the job from the job queue 511.

The job distributing section 502 refers to the job queue 511 and the system management information 512, and selects the image analyzing servers 304 to which to assign jobs on the basis of the processing performance of each of the image analyzing servers 304 and a present load on each of the image analyzing servers 304.

The system management information 512 includes the address information of the image analyzing servers 304 as well as information about the performance and the operation states of the image analyzing servers 304. The system management information 512 can indicate whether or not each of the image analyzing servers 304 implemented in the image processing system 300 is operating as well as the number of cores implemented in each of the image analyzing servers 304 and the number of currently operating cores. The system management information 512 may indicate only the presence or absence of operation of each of the image analyzing servers, and may indicate the present processing performance of each of the image analyzing servers 304 by another item.

The job distributing section 502 allocates jobs to the image analyzing servers 304 so as to distribute loads appropriately on the basis of the present performance of the image analyzing servers 304 indicated by the system management information 512 and the present loads on the image analyzing servers 304 indicated by the job queue 511. The job distributing section 502 receives results of the jobs, that is, image analysis results from the image analyzing servers 304, and stores the results in the common storage of the image processing system 300 via the storage control server 301. In a case where an analysis result indicates a non-detection of a defect, the job distributing section 502 deletes target image information (image data and accompanying information) from the common storage.

When there is free space to spare in the common storage, the target image information may be retained without being deleted immediately. Another trigger for performing the deletion may be a time at which the free space of the common storage becomes lower than a certain threshold value, or the deletion may be performed periodically at fixed times.

The system managing section 504 manages the system management information 512. The system managing section 504 communicates with each of the image analyzing servers 304, and obtains information about a present operation state thereof. The system managing section 504 makes a necessary update in the system management information 512 on the basis of the obtained information. The system managing section 504 communicates with the control terminal 112, and provides information for the control terminal 112 to control the SEM electron optical system.

In response to a request from the user terminal 302, the analysis result collecting section 503 collects a result of image analysis of the wafer as the sample 200, that is, a defect inspection result of the wafer from the common storage within the image processing system 300, and transmits the result to the user terminal 302. The user can check the defect inspection result of the sample 200 on the user terminal 302. The inspection result indicates, for example, the kind of a defect detected on the wafer and the position of the defect on the wafer.

FIG. 8 schematically illustrates an example of a software configuration of an image analyzing server 304. The image analyzing server 304 executes jobs of image analysis and defect detection. Each logical configuration of the image analyzing server 304 can be implemented by a processor that operates according to an instruction code of a program or a storage area of a storage device.

The image analyzing server 304 includes a computing section 530 and a storage section 540. The computing section 530 includes a defect detecting section 531, a defect image classifying section 532, an image processing section 533, a storage processing section 534, and a job monitoring section 535. The storage section 480 stores image information 541, a storage correspondence table 542, and an analysis result 543.

The storage section 540 includes a part of the common storage of the image processing system 300. The image information 541 and the analysis result 543 are stored in an area of the common storage. The storage correspondence table 542 is, for example, stored in a local area of the image analyzing server 304, and is referred to and updated by only the image analyzing server 304 in question.

The image information 541 includes image data and accompanying information transferred from the control terminal 112. The analysis result 543 is an analysis result of an image. The storage correspondence table 542 manages correspondence relation between addresses of the common storage of the image processing system 300 and addresses of the auxiliary storage devices of the image analyzing servers 304. In addition, the storage section 540 stores management information about the storage areas and the processors within the image analyzing servers 304. The information about the storage areas may include information such as a usable capacity, a usage area, and a free space.

The storage processing section 534 communicates with the storage control section 451 of the storage control server 301, and reads and writes data from and to the common storage. The storage processing section 534 receives an access request from the storage control section 451 together with a specified address of the common storage. The storage processing section 534 refers to the storage correspondence table 542, and accesses a storage area of the auxiliary storage device which storage area corresponds to the specified address.

The job monitoring section 535 communicates with the job distributing section 502 of the job server and receives a job, and notifies of completion of the job together with a result of the job. The job monitoring section 535 obtains specified image information via the storage control server 301. The job monitoring section 535 issues instructions to other functional sections (program modules) within the image analyzing server 304, and thereby controls and manages the execution of the job specified by the job distributing section 502. The job monitoring section 535 transmits, to the job distributing section 502, the result of the job, that is, an analysis result of the image for defect detection.

In response to an instruction from the job monitoring section 535, the image processing section 533 performs image preprocessing such as smoothing and contrast adjustment and transformation such as the movement and rotation of the image. In response to an instruction from the job monitoring section 535, the defect detecting section 531 detects a defective part from the preprocessed image. The defect detecting section 531 can, for example, detect a defect in the specified image by detecting a difference between a reference image and the specified image.

In response to an instruction from the job monitoring section 535, the defect image classifying section 532 classifies the kind of the defect detected by the defect detecting section 531 according to a classification criterion set in advance. The job monitoring section 535 returns, to the job distributing section 502, an analysis result indicating the presence or absence of defect detection and the position coordinates and the kind of the detected defect. The job monitoring section 535 may store the analysis result indicating the presence or absence of defect detection and the position coordinates and the kind of the detected defect in the common storage, and return only completion of defect detection processing and an address in the common storage of the stored information. In that case, the job distributing section 502 reads the necessary information from the common storage.

A system according to one embodiment of the present specification dynamically changes the performance of image transmission to the common storage of the image processing system 300 on the basis of the image processing performance of the image processing system 300. It is thereby possible to reduce a possibility of the occurrence of a shortage of storage areas of the image processing system 300 due to unprocessed image information and a consequent stop of the scanning of the SEM.

The image transmission performance is the performance of the generation of an image of the sample 200 and the transfer of the image to the image processing system 300 by the SEM and the control terminal 112. A system including the control terminal 112 and the image processing system 300 may be referred to as a control and image processing system.

When the image transmission performance is increased or decreased, an average amount of data per unit time received by the image processing system 300 is increased or decreased. That is, a time for transmitting the image information of one image is increased or decreased. The image transmission performance includes a speed of output of a detection signal of signal electrons for generating one image in the SEM electron optical system (detection signal output performance), a speed of generation of the transfer image by the control terminal 112 (image generation performance), and a speed of image transfer from the control terminal 112 to the image processing system 300 (image transfer performance).

The performance (speed) of obtainment of a detection signal from the SEM via the computing unit 111 and generation of an image by the control terminal 112 may be referred to as scanning performance. The scanning performance depends on the detection signal output performance and the image generation performance described above. The scanning performance is increased or decreased according to an increase or decrease in the detection signal output performance or the image generation performance. In the following, description will be made of an example in which the scanning performance is dynamically controlled according to the processing performance of the image processing system 300.

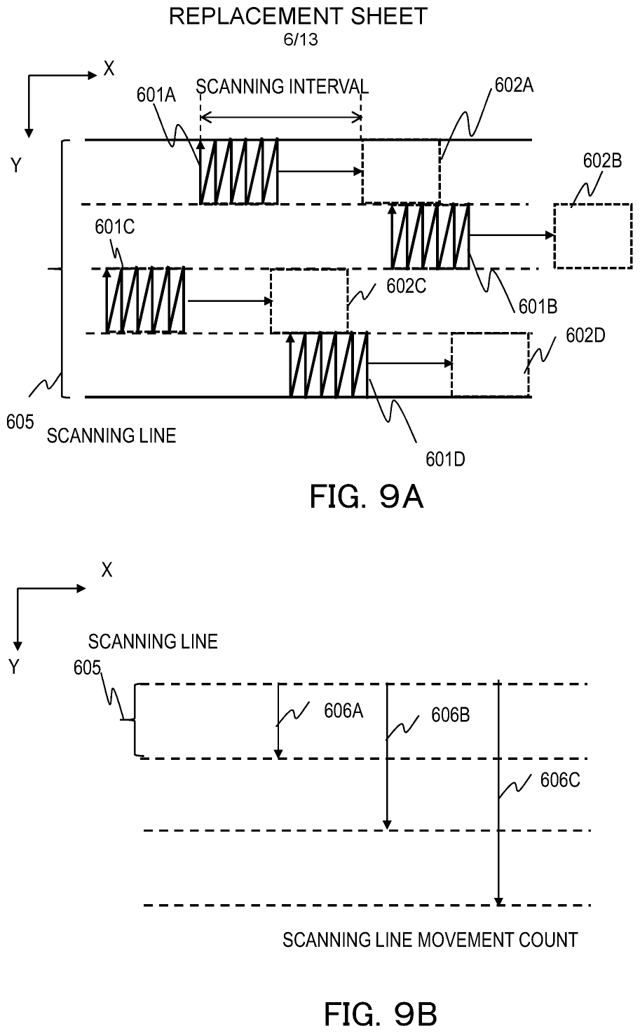

First, description will be made of indexes indicating the scanning performance in the SEM electron optical system. The scanning performance of the SEM optical system can be expressed by, for example, a scanning interval or a scanning line movement count. In the following, scanning intervals and scanning lines will be described with reference to FIGS. 9A and 9B. FIGS. 9A and 9B illustrate an example of a scanning method. Features of the present disclosure can be applied to a scanning method different from this scanning method.

FIG. 9A is a schematic diagram of assistance in explaining scanning intervals. In FIG. 9A, four primary beams are applied to the sample. Scanning unit regions 601A to 601D are regions irradiated with the four primary beams simultaneously while the four primary beams are deflected by the deflector 106 in a state in which the stage 108 is stopped. Arrows indicate the trajectories of the primary beams. The primary beams scan the respective scanning unit regions. The scanning unit regions 601A to 601D have a common shape.

The control terminal 112 performs a raster scanning by the four primary beams on an observation region on the sample 200. The control terminal 112 irradiates the scanning unit regions by the four primary beams, and thereafter shifts the regions irradiated with the four primary beams along an X-axis by controlling the stage 108. In the example of FIG. 9A, after the irradiation of the scanning unit regions 601A to 601D, scanning unit regions 602A to 602D are irradiated. A region in which the four primary beams move along the X-axis will be referred to as a scanning line 605.

The control terminal 112 irradiates the whole or a part of the region of one scanning line 605 while moving the four primary beams in one direction along the X-axis. Thereafter, the control terminal 112 shifts the regions irradiated with the four primary beams along a Y-axis by controlling the stage 108. The control terminal 112 irradiates a next scanning line 605 while moving the four primary beams along the X-axis. An interval between the defined scanning lines 606 is, for example, the same as the length (width) along the Y-axis of the scanning lines 606. These may differ depending on settings.

Intervals between the scanning unit regions adjacent to each other along the Y-axis are equal to the length along the Y-axis of the scanning unit regions. The scanning unit regions 601A to 601D occupy different coordinate regions on the Y-axis, and the positions on the Y-axis of the adjacent scanning units coincide with those of the scanning unit regions 601A to 601D. The intervals between the scanning unit regions along the Y-axis may be different from the length along the Y-axis of the scanning unit regions.

In FIG. 9A, after the irradiation of the scanning unit regions 601A to 601D, the stage 108 is moved along the X-axis, and the primary beams scan (irradiate) the respective regions 602A to 602D. Intervals between the scanning unit regions irradiated with the same primary beams, the scanning unit regions being consecutive along the X-axis, will be referred to as scanning intervals. The primary beams sequentially irradiate the scanning unit regions along the X-axis at the same scanning interval.

In a case where the scanning interval is equal to or less than the length along the X-axis of the scanning unit regions, the primary beams can irradiate the whole region extending in the X-axis direction by one movement along the X-axis. In a case where the scanning interval is longer than the length along the X-axis of the scanning unit regions, there is a gap between the scanning unit regions adjacent to each other along the X-axis. In order to irradiate the whole region along the X-axis, the primary beams are scanned a plurality of times along the X-axis at an identical position on the Y-axis.

The scanning unit regions 601A to 601D are present at different positions on the Y-axis. The intervals between the regions adjacent to each other on the Y-axis coincide with the length along the Y-axis of the regions. In a case where the scanning interval is smaller than the length along the X-axis of the scanning unit regions, the entire region of the scanning line 605 can be irradiated by one movement of the four primary beams along the X-axis.

FIG. 9B illustrates a plurality of consecutive scanning lines 605. In FIG. 9B, one scanning line is indicated by reference numeral 605 as an example. In the example of FIG. 9B, the widths and intervals of the scanning lines 605 coincide with each other.

The control terminal 112 selects a scanning line 605 to be irradiated next according to a set scanning line movement count. Arrows 606A, 606B, and 606C respectively represent scanning line movement counts of 1, 2 and 3. For example, in a case where the scanning line movement count is 1, an adjacent scanning line 605 is selected. In a case where the scanning line movement count is 2, a next scanning line but one is selected. In a case where the scanning line movement count is 3, a third scanning line 605 ahead of the present scanning line 605 whose irradiation is completed is selected.

In the case where the scanning line count is 1, all of scanning lines in the observation region can be irradiated by one movement along the Y-axis of the primary beams. In the case where the scanning line count is 2, the primary beams need to be moved twice along the Y-axis in order to irradiate all of the scanning lines in the observation region. Similarly, in a case where the scanning line count is N (natural number), the primary beams need to be moved N times along the Y-axis in order to irradiate all of the scanning lines in the observation region.

As is understood from the above description, in a case where the irradiated regions necessary to generate an image of the observation region are the same, the number of times of raster scanning of the entire observation region is increased when the scanning interval or the scanning movement count is increased. Therefore, a time taken to obtain all detection signals for generating an image of the observation region is lengthened. That is, the scanning performance in the SEM optical system is increased or decreased by increasing or decreasing the scanning interval or the scanning movement count.

One embodiment of the present specification changes the scanning interval and/or the scanning line movement count according to the image processing performance of the image processing system 300. Thus, by increasing or decreasing the scanning performance according to an increase or decrease in the image processing performance, it is possible to suppress the occurrence of a shortage of free space for storing image information in the image processing system 300.

When a resolution necessary for defect inspection is obtained, the irradiation of a partial region with the primary beams may be skipped. As described above, when the scanning interval or the scanning line movement count is increased, an image resolution is decreased, and an amount of image data is decreased. This decreases an amount of data per time transmitted to the image processing system 300, that is, the image transmission performance.

In one embodiment of the present specification, the control terminal 112 obtains information about the image processing performance from the image processing system 300, refers to the processing performance table 433 and the scanning performance table 434, and determines the scanning performance of the SEM optical system.

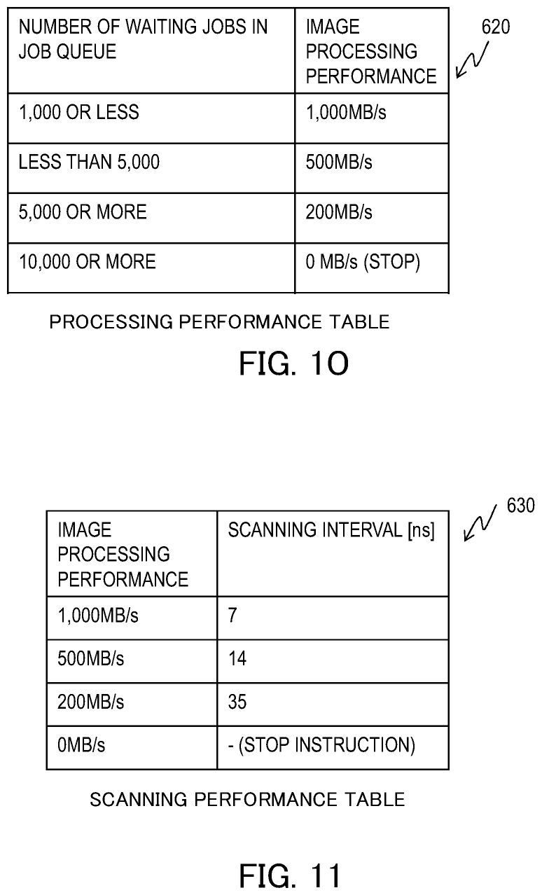

FIG. 10 illustrates an example of a configuration of the processing performance table 433. A processing performance table 620 associates the number of waiting jobs in the job queue 511 with the image processing performance of the image processing system 300. Specifically, a plurality of divisions for the number of waiting jobs are defined. An image processing performance is assigned to each of the divisions.

In the example of FIG. 10, four divisions of 1000 or less, 1001 to 5000, 5000 to 9999, and 10000 or more are defined. A lower image processing performance is associated with a division of a larger number of waiting jobs. A stop of the image processing is associated with the division of 10000 or more. Thus, the number of waiting jobs is used as an index of the image processing performance.

FIG. 11 illustrates an example of a configuration of the scanning performance table 434. A scanning performance table 630 associates the image processing performance with the scanning interval. Specifically, a scanning interval is assigned to each value of the image processing performance indicated by the processing performance table 620. The smaller the value of the image processing performance, the larger the value of the assigned scanning interval. A scanning stop (scanning interval exceeding a maximum value) is associated with an image processing performance of 0 MB/s.

The system monitoring and control section 422 of the control terminal 112 obtains the value of the number of waiting jobs from the image processing system 300 periodically, for example. The system managing section 504 of the job server 303 can obtain the number of waiting jobs in the job queue according to a request from the system monitoring and control section 422, and return the number of waiting jobs in the job queue to the system monitoring and control section 422.

The system monitoring and control section 422 refers to the processing performance table 620 and determines an image processing performance corresponding to the obtained number of waiting jobs, and further refers to the scanning performance table 630 and determines a scanning interval corresponding to the determined image processing performance. When the determined scanning interval is different from the present scanning interval, the system monitoring and control section 422 sets the new scanning interval as the control parameter 432, and gives an instruction for the new scanning interval to the control section 410. In one embodiment of the present specification, the system monitoring and control section 422 updates also other control parameters necessary to scan the whole of the observation region. The number of raster scans in the observation region, initial irradiation positions of the primary beams in each raster scan, and the like can be updated.

As described above, when the scanning interval is increased, more time becomes necessary to generate image data, and consequently the speed of transmission of image information to the image processing system 300 (transmission performance) is decreased. It is thereby possible to reduce a possibility of the occurrence of a shortage of free space in the image processing system 300. Incidentally, when possible in design, an amount of data of an image may be reduced by skipping the irradiation of a part of the observation region.

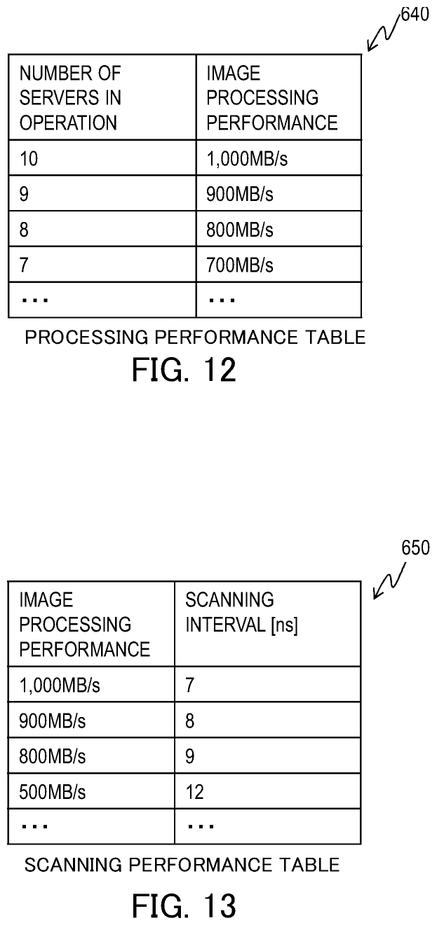

Another example of the processing performance table and the scanning performance table will next be described. FIG. 12 illustrates an example of a configuration of the processing performance table 433. A processing performance table 640 associates the number of servers in operation among the image analyzing servers 304 with the image processing performance of the image processing system 300. Specifically, image processing performances are assigned to divisions of the number of servers in operation. In the example of FIG. 12, each of the divisions is formed with one value. A lower image processing performance is associated with a division of a smaller number of servers in operation.

Thus, the number of servers in operation of the image analyzing servers 304 is used as an index of the image processing performance. Another embodiment of the present specification associates the number of cores in operation of the image analyzing servers 304 with the image processing performance in place of the number of servers in operation. The number of cores in operation is a total number of cores operating in all of the image analyzing servers 304. The number of implemented cores of the image analyzing servers 304 is fixed. The number of servers in operation therefore represents the number of cores in operation. Thus, the processing performance of the image analyzing servers 304 as a whole can be expressed by the number of cores in operation or the number of servers in operation.

FIG. 13 illustrates an example of a configuration of the scanning performance table 434. A scanning performance table 650 associates the image processing performance with the scanning interval. Specifically, a scanning interval is assigned to each value of the image processing performance indicated by the processing performance table 640. The smaller the value of the image processing performance, the larger the value of the assigned scanning interval. A scanning stop (scanning interval exceeding a maximum value) is associated with an image processing performance of 0 MB/s not illustrated in the figure.

The system monitoring and control section 422 of the control terminal 112 obtains information about the number of servers in operation from the image processing system 300 periodically, for example. The system managing section 504 of the job server 303 can obtain the number of servers in operation according to a request from the system monitoring and control section 422, and return the number of servers in operation to the system monitoring and control section 422.

The system monitoring and control section 422 refers to the processing performance table 640 and determines an image processing performance corresponding to the obtained number of servers in operation, and further refers to the scanning performance table 650 and determines a scanning interval corresponding to the determined image processing performance. When the determined scanning interval is different from the present scanning interval, the system monitoring and control section 422 sets the new scanning interval as the control parameter 432, and gives an instruction for the new scanning interval to the control section 410.

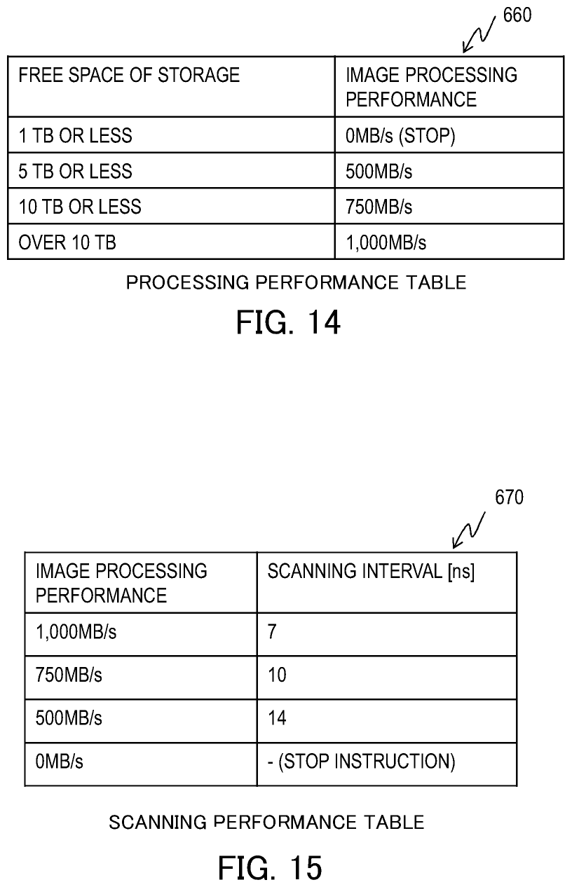

Another example of the processing performance table and the scanning performance table will next be described. FIG. 14 illustrates an example of a configuration of the processing performance table 433. A processing performance table 660 associates the size of storage free space of the common storage of the image processing system 300 with the image processing performance of the image processing system 300. The free space size corresponds to the size of an area that can store image information.

Specifically, image processing performances are assigned to divisions of the free space size. A lower image processing performance is associated with a division of a smaller free space. Incidentally, the free space and the usage area are equivalent to each other. A higher image processing performance is associated with a larger usage area. Thus, the storage free space of the image analyzing server 304 is used as an index of the image processing performance.

FIG. 15 illustrates an example of a configuration of the scanning performance table 434. A scanning performance table 670 associates the image processing performance with the scanning interval. Specifically, a scanning interval is assigned to each value of the image processing performance indicated by the processing performance table 660. The smaller the value of the image processing performance, the larger the value of the assigned scanning interval. A scanning stop (scanning interval exceeding a maximum value) is associated with an image processing performance of 0 MB/s.

The system monitoring and control section 422 of the control terminal 112 obtains information about the storage free space size from the image processing system 300 periodically, for example. The system managing section 504 of the job server 303 can obtain the free space size according to a request from the system monitoring and control section 422, and return the free space size to the system monitoring and control section 422.

The system monitoring and control section 422 refers to the processing performance table 660 and determines an image processing performance corresponding to the obtained free space size, and further refers to the scanning performance table 670 and determines a scanning interval corresponding to the determined image processing performance. When the determined scanning interval is different from the present scanning interval, the system monitoring and control section 422 sets the new scanning interval as the control parameter 432, and gives an instruction for the new scanning interval to the control section 410.

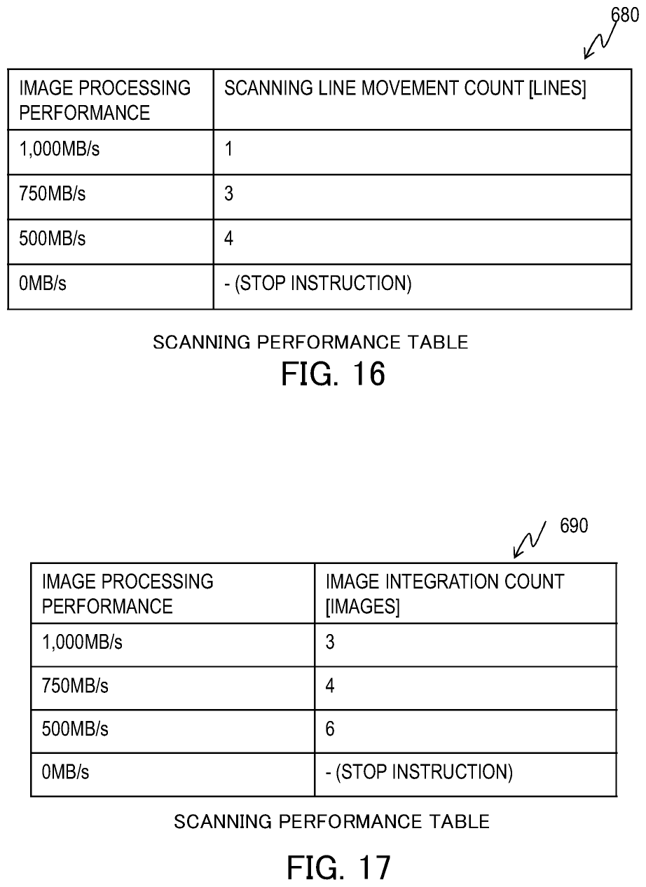

An example of another scanning performance table will next be described. FIG. 16 illustrates an example of a configuration of the scanning performance table 434. A scanning performance table 680 associates the image processing performance with the scanning line movement count. The scanning line movement count has been described with reference to FIG. 9B. The scanning performance of the SEM can be changed by changing the scanning line movement count.

A scanning line movement count is assigned to each value of the image processing performance in the processing performance table 433. The smaller the value of the image processing performance, the larger the value of the assigned scanning line movement count. A scanning stop (scanning interval exceeding a maximum value) is associated with an image processing performance of 0 MB/s.

An example of another scanning performance table will next be described. FIG. 17 illustrates an example of a configuration of the scanning performance table 434. A scanning performance table 690 associates the image processing performance with an image integration count. The image integration count represents the number of images that are integrated to generate an image to be transmitted to the image processing system 300. The image integration count is an index indicating the scanning performance of the SEM apparatus.

The image generating section 413 of the control terminal 112 generates a plurality of images of the observation region from detection signals obtained by a plurality of scans of the whole of the same observation region or a plurality of times of scanning of each scanning unit region. The image generating section 413 generates one image by integrating the plurality of generated images. A clearer image can be thereby obtained.

In order to integrate a larger number of images, the scanning of the observation region by the primary beams needs more time. Therefore, when the integration count is increased, an amount of data per time of the image information transferred to the common storage of the image processing system 300 is decreased. Hence, in the scanning performance table 690 illustrated in FIG. 17, a larger image integration count is assigned to a lower image processing performance. A scanning stop (scanning interval exceeding a maximum value) is associated with an image processing performance of 0 MB/s.

As described above, there are a few indexes indicating the scanning performance of the SEM apparatus, and these indexes include the scanning interval, the scanning line movement count, and the image integration count. These indexes enable the scanning performance, that is, the performance of image transmission to the common storage to be changed effectively according to the image processing performance.

An example of another index is the number of primary beams simultaneously applied to the sample 200. The number of primary beams selected from the primary beams that can be applied may be associated with the image processing performance. The control terminal 112 repeats the raster scanning of the observation region a plurality of times by different primary beam groups. The whole of the observation region is irradiated with the primary beams by a plurality of times of scanning, and an image is generated from detection signals of these scans. Therefore, the smaller the number of simultaneously applied beams, the larger the number of scans, and the more the time necessary for image generation. Hence, a smaller number of primary beams is assigned to a lower image processing performance.

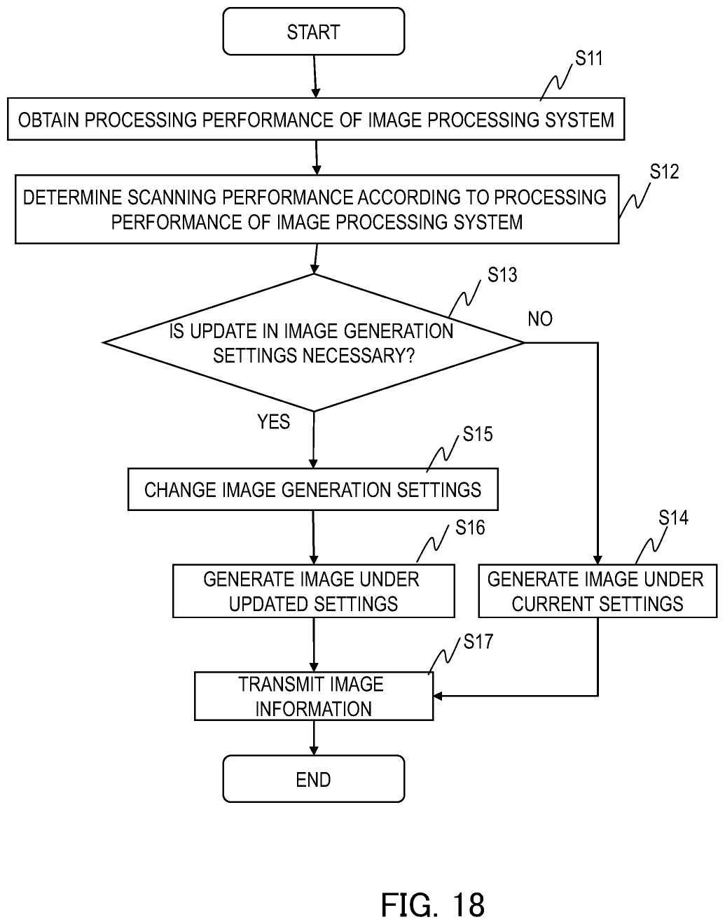

FIG. 18 illustrates a flowchart of an example of control processing on the SEM electron optical system by the control terminal 112. The system monitoring and control section 422 obtains an index indicating an image processing performance from the image processing system 300 (S11). The system monitoring and control section 422 refers to the processing performance table 433 and the scanning performance table 434, and determines a scanning performance (S12).

The system monitoring and control section 422 refers to the control parameter 432, compares a control parameter value based on the determined scanning performance with a present parameter value, and determines whether or not an update in settings for image generation is necessary (S13).

When the update in the settings is not necessary (S13: NO), the present control parameter 432 is maintained, and the control section 410 generates an SEM image according to the maintained control parameter 432 (S14). When the update in the settings is necessary (S13: YES), the system monitoring and control section 422 updates the value of the control parameter 432 (S15). The control section 410 generates an SEM image according to the updated control parameter 432 (S16). The image information transmitting section 423 transmits the generated image and accompanying information to the image processing system 300 (S17).

The foregoing embodiment dynamically controls the scanning performance of the SEM apparatus according to the processing performance of the image processing system 300. The control terminal 112 in one embodiment of the present specification dynamically changes the performance of transfer of image information to the image processing system 300 on the network 310 in place of the scanning performance of the SEM apparatus. It is thereby possible to change the performance of transmission of the image information to the common storage of the image processing system 300.

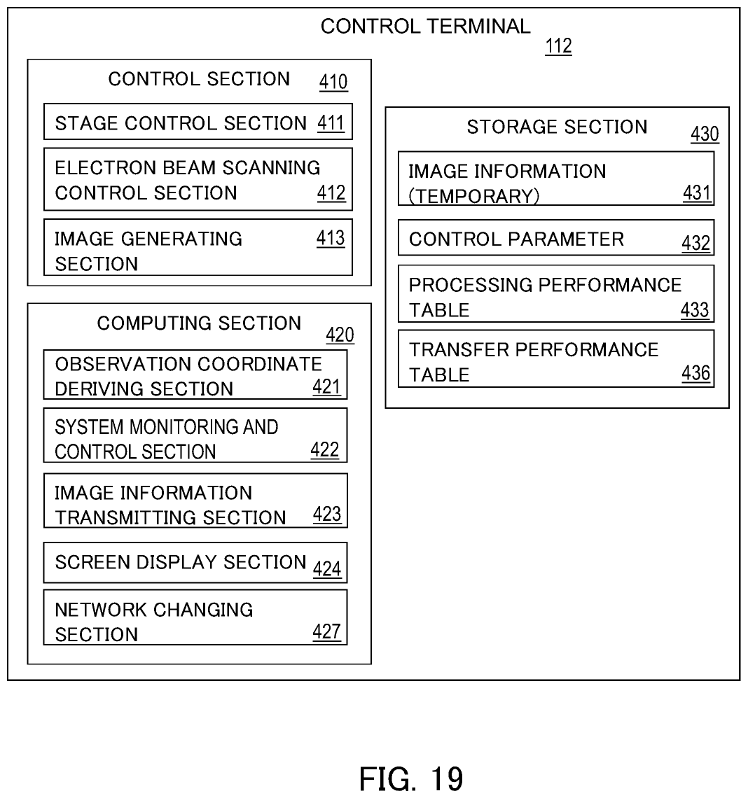

FIG. 19 illustrates an example of a software configuration of the control terminal 112 according to one embodiment of the present specification. A comparison with the configuration example illustrated in FIG. 4 indicates that a network changing section 427 is added to the computing section 420. In addition, in place of the scanning performance table 434, a transfer performance table 436 is stored in the storage section 430.

The network changing section 427 changes the performance of data transmission from the control terminal 112 to the image processing system 300 via a network according to an instruction from the system monitoring and control section 422. The transfer performance table 436 manages transfer performance (transmission performance) on the network which transfer performance corresponds to the image processing performance indicated by the processing performance table 433. The system monitoring and control section 422 refers to the processing performance table 433 and the transfer performance table 436, and determines a transfer performance value corresponding to an image processing performance index obtained from the image processing system 300.

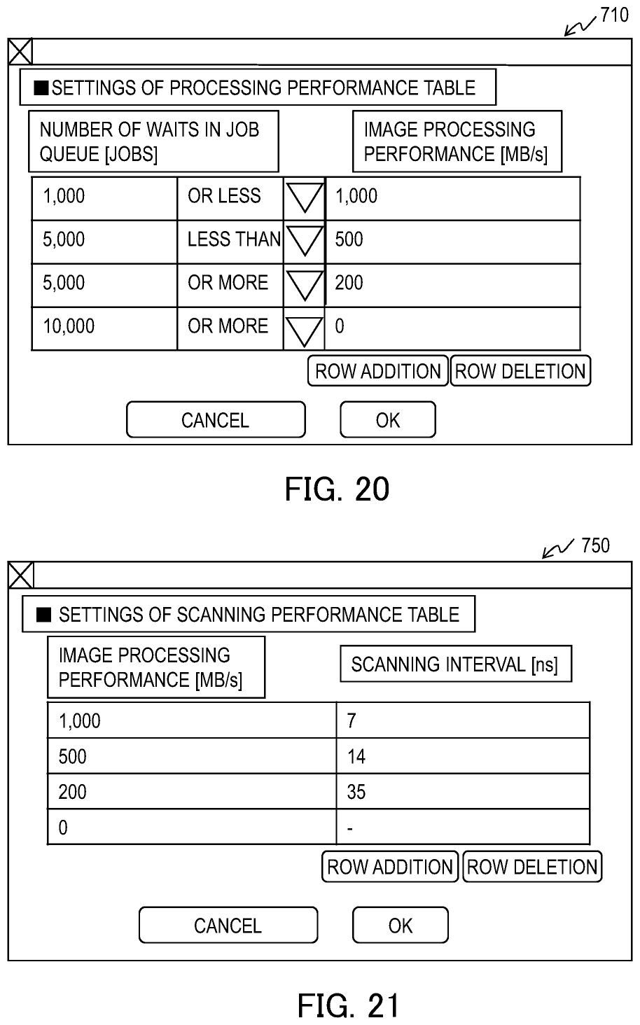

An example of setting of the processing performance table and the scanning performance table by the user will next be described. FIG. 20 illustrates an example of a GUI image for setting the processing performance table. The screen display section 424 displays a GUI image 710 on an output device of the user terminal 302. The GUI image 710 enables the user to set the processing performance table by using an input device. The GUI image 710 is an image for defining relation between the number of waiting jobs and the image processing performance. The user can add a record to the table by a “row addition” button, and delete a record by a “row deletion” button. When an “OK” button is selected, the screen display section 424 reflects input information in the processing performance table 433.

FIG. 21 illustrates an example of a GUI image for setting the scanning performance table. The screen display section 424 displays a GUI image 750 on the output device of the user terminal 302. The GUI image 750 enables the user to set the scanning performance table by using the input device. The GUI image 750 is an image for defining relation between the image processing performance and the scanning interval. The user can add a record to the table by a “row addition” button, and delete a record by a “row deletion” button. When an “OK” button is selected, the screen display section 424 reflects input information in the scanning performance table 434.

The present invention is not limited to the foregoing embodiments, but includes various modifications. For example, the foregoing embodiments are described in detail to describe the present invention in an easily understandable manner, and are not necessarily limited to embodiments including all of the described configurations. In addition, a part of a configuration of a certain embodiment can be replaced with a configuration of another embodiment, and a configuration of another embodiment can be added to a configuration of a certain embodiment. In addition, for a part of a configuration of each embodiment, another configuration can be added, deleted, or substituted.

In addition, a part or the whole of configurations, functions, processing units, and the like described above may be implemented by hardware by making design thereof by an integrated circuit, for example. In addition, configurations, functions, and the like described above may be implemented by software through the interpretation and execution of a program implementing each function by a processor. Information of the program implementing each function, a table, a file, and the like can be placed in a memory, a recording device such as a hard disk or an SSD (Solid State Drive), or a recording medium such as an IC card or an SD card. In addition, control lines and information lines considered to be necessary for description are illustrated, and not all of control lines and information lines in a product are necessarily illustrated. Almost all of configurations may be considered to be actually interconnected.

1. A charged particle beam microscope image processing system comprising:
a charged particle beam optical system configured to irradiate a sample with a charged particle beam, and output a detection signal of charged particles from the sample; and
a control and image processing system configured to control the charged particle beam optical system, generate an image of the sample from the detection signal, store the generated image in a storage, and perform analysis processing on the image,
the control and image processing system being configured to
determine a performance of processing the image on a basis of an operation state of the control and image processing system,
on a basis of the processing performance, determine a processing performance corresponding to a speed of storing the image into the storage, and
generate the image and store the image into the storage according to the determined processing performance.

2. The charged particle beam microscope image processing system according to claim 1, wherein
the control and image processing system controls a performance of output of the detection signal by the charged particle beam optical system for generation of the image according to the determined processing performance.

3. The charged particle beam microscope image processing system according to claim 2, wherein
the charged particle beam optical system is a scanning charged particle beam optical system configured to scan the sample by the charged particle beam, and
the control and image processing system controls the performance of output of the detection signal by controlling a scanning interval of the charged particle beam in a scanning line.

4. The charged particle beam microscope image processing system according to claim 2, wherein
the charged particle beam optical system is a scanning charged particle beam optical system configured to scan the sample by the charged particle beam, and
the control and image processing system controls the performance of output of the detection signal by controlling an interval between scanning lines in scanning of an observation region.

5. The charged particle beam microscope image processing system according to claim 1, wherein
the control and image processing system generates a plurality of images of an observation region of the sample, and generates the image by integrating the plurality of images, and
the control and image processing system controls number of the plurality of images according to the determined processing performance.

6. The charged particle beam microscope image processing system according to claim 1, wherein
the control and image processing system manages jobs of analysis processing of images stored in the storage, and
the control and image processing system determines the performance of processing the image on a basis of number of waiting jobs.

7. The charged particle beam microscope image processing system according to claim 1, wherein
the control and image processing system determines the performance of processing the image on a basis of a size of free space of the storage.

8. The charged particle beam microscope image processing system according to claim 1, wherein
the control and image processing system includes a plurality of computing cores configured to perform the analysis processing, and
the control and image processing system determines the performance of processing the image on a basis of number of cores in operation among the plurality of computing cores.

9. A control method of a charged particle beam microscope image processing system, the charged particle beam microscope image processing system including
a charged particle beam optical system configured to irradiate a sample with a charged particle beam, and output a detection signal of charged particles from the sample, and
a control and image processing system configured to control the charged particle beam optical system, generate an image of the sample from the detection signal, store the generated image in a storage, and perform analysis processing on the image,
the control method comprising:
determining a performance of processing the image on a basis of an operation state of the control and image processing system;
on a basis of the processing performance, determining a processing performance corresponding to a speed of storing the image into the storage; and
generating the image and storing the image into the storage according to the determined processing performance.
